(19) United States
(12) Patent Application Publication
(10) Pub. No.: US 2020/0288611 A1
(43) Pub. Date: Sep. 10, 2020

(54) MOUNTING SYSTEM

(71) Applicant: FUJI CORPORATION, Chiryu (JP)

(72) Inventor: Kenji HARA, Kasriya-shi (JP)

(73) Assignee: FUJI CORPORATION, Chiyu (JP)

(21) Appl. No.: 16/645,107

(22) PCT Filed: Sep. 15, 2017
(86) PCT No.: PCT/JP2017/033579

§ 371 Date: Mar. 6, 2020

(51) Int. Cl. H05K 13/08; H05K 13/04

(52) U.S. Cl. CPC H05K 13/081; H05K 13/04

(57) ABSTRACT

A mounting system including a component mounting device configured to mount a component on a surface of a board, and a control device. The component mounting device includes an imaging device to image the surface of the board. The control device stores drawing information depicting the board surface on which the component is to be mounted by the component mounting device, compares a specific position in the stored drawing information with a specific position in image information of the board surface imaged by the imaging device, and recognizes that the planned mounting section of the board surface is not at the predetermined position when the specific position in the drawing information and the specific position in the image information are different.

### TECHNICAL FIELD

The techniques disclosed herein relate to a mounting system.

### BACKGROUND ART

Patent Literature 1 discloses a component mounting device for mounting a component on a surface of a board. The component mounting device of Patent Literature 1 includes an imaging device, configured to image a surface of a board, and a control device. The control device determines the position at which the component is mounted based on the image captured by the imaging device.

### PATENT LITERATURE

Patent Literature 1: JP-A-2003-069288

### SUMMARY OF THE INVENTION

### Technical Problem

When a component is mounted on the surface of the board by the component mounting device, CAD data may be generated in advance in order to recognize the position where the component is mounted. The CAD data indicates the position at which the component is to be mounted on the surface of the board. The operator using the component mounting device can recognize the position where the component is to be mounted on the surface of the board by checking the CAD data. However, when the component is actually mounted on the surface of the board by the component mounting device, the actual position where the component is to be mounted on the board and the mounting position of the component indicated by the CAD data may be deviated from each other due to some cause. That is, although the actual position where the component is to be mounted on the board and the mounting position of the component indicated by the CAD data are supposed to match with each other, a positional deviation may occur between them. For example, a positional deviation may occur between the actual board and CAD data due to a discrepancy between the design drawing and the actual board in the board manufacturing process or the like. In such a case, the operator using the component mounting device can check whether a positional deviation has occurred between the actual board and the CAD data, but time is required for such a confirmation operation. In addition, if a positional deviation has occurred, there is a possibility that the component cannot be mounted at the correct position on the board surface. Therefore, the present specification provides a technique capable of easily determining whether a component can be mounted at the correct position.

### Solution to Problem

The mounting system disclosed in this specification includes a component mounting device, configured to mount a component on a surface of a board, and a control device. The surface of the board has a planned mounting section, at which mounting of a component by the component mounting device is planned. The component mounting device includes an imaging device for imaging the board surface, and the mounting device is configured to mount a component on the planned mounting section when the planned mounting section of the board surface is at a predetermined position. The control device stores drawing information, depicting the board surface on which a component is to be mounted by the component mounting device, compares the specific position in the stored drawing information with a specific position in image information of the board surface imaged by the imaging device, and recognizes that the planned mounting section of the board surface is not at a predetermined position when the two specific positions are different from each other.

With this configuration, by comparing the specific position in the drawing information and the specific position in the image information, it is possible to recognize whether there is a positional deviation between them. When the specific position in the drawing information and the specific position in the image information are different from each other, the control device recognizes that the planned mounting section on the board surface of the board is not at the predetermined position. As a result, it is possible to determine whether the planned mounting section is at the original intended position for mounting the component. Even if the operator using the component mounting device does not visually check the actual board, it is possible to determine whether the planned mounting section is at the original intended position. If the planned mounting section is not at the original intended position, it can be determined that the component cannot be mounted at the correct position. Otherwise, it is determined that the component can be mounted at the correct position. As described above, it is possible to easily determine whether a component can be mounted at a correct position.

### BRIEF DESCRIPTION OF DRAWINGS

FIG. 1 A block diagram of a mounting system of an embodiment.

FIG. 2 A side view schematically showing a configuration of the mounting system of the embodiment.

FIG. 3 A side view of a circuit board and an electronic component of the embodiment.

FIG. 4 A top view of the circuit board of the embodiment.

FIG. 5 A flowchart of a position comparison process executed in the mounting system of the embodiment.

FIG. 6 An enlarged view of main part VI of FIG. 4.

FIG. 7 A top view of a circuit board of another embodiment.

### DESCRIPTION OF EMBODIMENTS

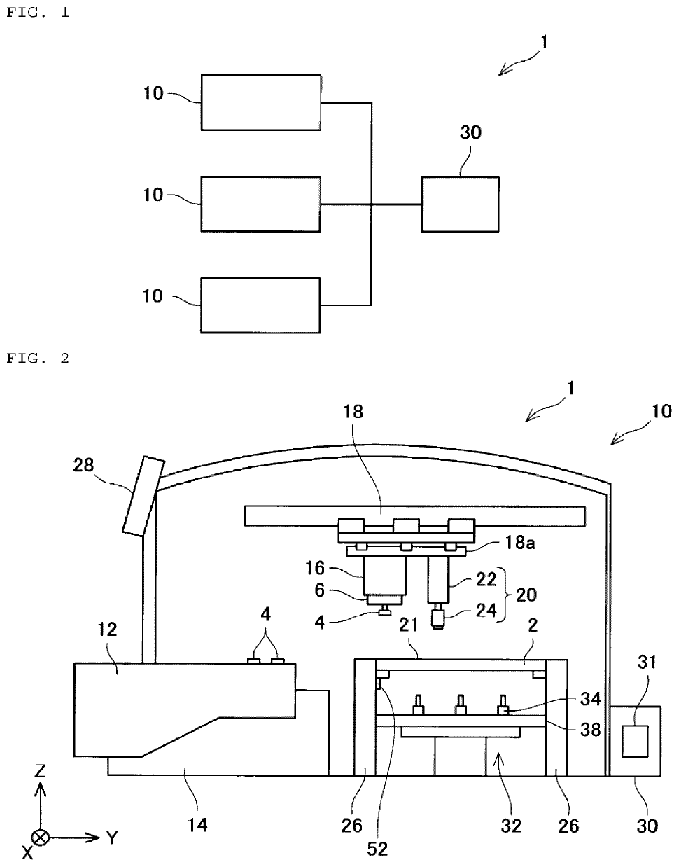

Mounting system 1 of an embodiment will be described with reference to the drawings. As shown in FIG. 1, mounting system 1 of the embodiment includes multiple component mounting devices 10 and control device 30.

First, component mounting device 10 will be described. In the following, one representative component mounting device 10 among the multiple component mounting devices 10 will be described. Component mounting device 10 is a device for mounting multiple electronic components on a circuit board. Component mounting device 10 is also referred to as a surface mounting device or a chip mounter. Normally, component mounting device 10 is provided together with a solder printing device, another component mounting device, and a board inspection device, and constitutes a series of mounting line.

As shown in FIG. 2, component mounting device 10 includes multiple component feeders 12 (one representative component feeder 12 is shown in FIG. 2), feeder holding section 14, mounting head 16, imaging unit 20, moving mechanism 18 for moving mounting head 16 and imaging unit 20, conveyance device 26, and operation panel 28.

Each component feeder 12 accommodates multiple electronic components 4. Each component feeder 12 is a device for supplying multiple electronic components 4 to be mounted on circuit board 2. Each component feeder 12 is attached to feeder holding section 14 in an exchangeable manner and supplies electronic components 4 to mounting head 16. Each component feeder 12 is, for example, a tape-type feeder that accommodates multiple electronic components 4 in a wound-tape format. Each component feeder 12 supplies electronic components 4 by feeding out a tape in which multiple electronic components 4 are arranged in a line. The specific configuration of component feeder 12 is not particularly limited. Each component feeder 12 may be a tray-type feeder that accommodates multiple electronic components 4 on a tray or a bulk-type feeder that randomly accommodates multiple electronic components 4 in a container.

Moving mechanism 18 moves mounting head 16 and imaging unit 20 between component feeder 12 and circuit board 2. Moving mechanism 18 of the present embodiment is an XY robot that moves movement base 18a in the X-direction and the Y-direction. Moving mechanism 18 includes guide rails for guiding movement base 18a, a moving mechanism for moving movement base 18a along the guide rails, a motor for driving the moving mechanism, and the like. Moving mechanism 18 is disposed above component feeder 12 and circuit board 2. Mounting head 16 and imaging unit 20 are attached to movement base 18a. Mounting head 16 and imaging unit 20 are moved above component feeder 12 and above circuit board 2 by moving mechanism 18.

Mounting head 16 includes suction nozzle 6 that picks up electronic components 4. Suction nozzle 6 is detachable from mounting head 16. Suction nozzle 6 is attached to mounting head 16 so as to be movable in the Z-direction.

Suction nozzle 6 is configured to move up and down in the up-down direction and pick up electronic components 4 by suction, suction nozzle 6 being moved up and down by an actuator (not shown) accommodated in mounting head 16. In order to mount electronic component 4 on circuit board 2 by mounting head 16, first, mounting head 16 is moved to a component suction position by moving mechanism 18. Next, suction nozzle 6 is moved downward until the lower surface of suction nozzle 6 comes into contact with electronic component 4 accommodated in component feeder 12. Next, electronic component 4 is picked up by suction nozzle 6, and suction nozzle 6 is then moved upward. Next, mounting head 16 is moved to a component mounting position by moving mechanism 18 and is positioned with respect to circuit board 2. Next, by lowering suction nozzle 6 toward circuit board 2, electronic component 4 is mounted on circuit board 2.

Imaging unit 20 is attached to movement base 18a. Therefore, when mounting head 16 moves, imaging unit 20 also moves integrally. Imaging unit 20 includes camera support 22 and camera 24 (an example of an imaging device). Camera support 22 is attached to movement base 18a. Camera 24 is attached to camera support 22.

Camera 24 is a device for imaging surface 21 of circuit board 2. When imaging unit 20 is moved by moving mechanism 18 to a position above circuit board 2, camera 24 is disposed above circuit board 2. Camera 24 images surface 21 of circuit board 2 from above circuit board 2 in a state in which the entire surface 21 of circuit board 2 falls within an imaging range. Image data of surface 21 of circuit board 2 imaged by camera 24 is transmitted to control device 30. Camera 24 includes a camera control device (not shown) for controlling the operation of camera 24. The operation of camera 24 is controlled by the camera control device.

Conveyance device 26 is a device for conveying circuit board 2 into component mounting device 10, conveying and positioning circuit board 2 to the component mounting position, and conveying circuit board 2 out of component mounting device 10. Conveyance device 26 of the present embodiment can be configured by, for example, a pair of belt conveyors, supporting device 32 attached to the belt conveyors and supporting circuit board 2 from below, and a driving device for driving the belt conveyors. Circuit board 2 is conveyed in the X-direction shown in the drawing.

Supporting device 32 includes support table 38 and multiple support pins 34. Support table 38 and multiple support pins 34 are disposed below circuit board 2. Support table 38 is configured to be movable in the up-down direction. Multiple support pins 34 are fixed to support table 38 and protrude upward. In supporting device 32, when circuit board 2 is conveyed to a predetermined work position by the belt conveyors, support table 38 disposed below circuit board 2 rises. As support table 38 rises, the multiple support pins 34 fixed to support table 38 lift circuit board 2 upward. Operation panel 28 is an input device for receiving instructions from an operator. Various information is displayed on operation panel 28.

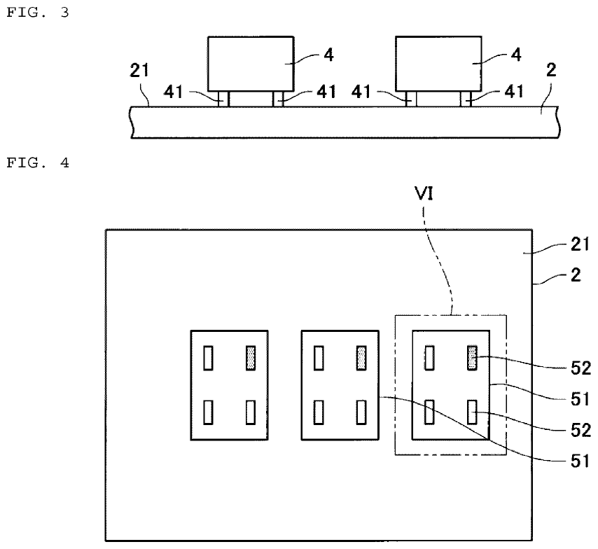

Component mounting device 10 mounts multiple electronic components 4 on circuit board 2. As shown in FIG. 3, multiple electronic components 4 are mounted on surface 21 of circuit board 2. Each electronic component 4 includes multiple electrodes 41. When electronic component 4 is mounted on surface 21 of circuit board 2, multiple electrodes 41 of electronic component 4 are fixed to surface 21 of circuit board 2. Multiple electrodes 41 are made of metal and are electrically conductive.

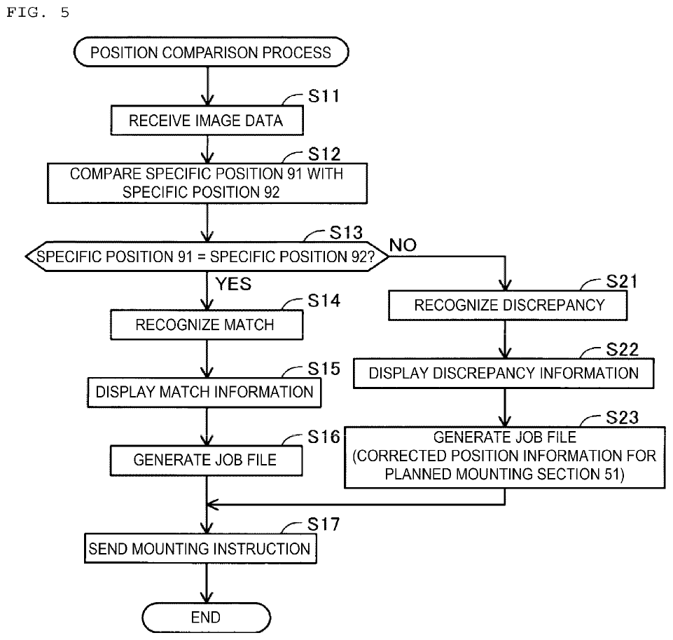

As shown in FIG. 4, circuit board 2 on which multiple electronic components 4 are to be mounted includes multiple planned mounting sections 51 and multiple planned electrode sections 52. Multiple planned mounting sections 51 and multiple planned electrode sections 52 are formed on surface 21 of circuit board 2. Multiple planned mounting sections 51 and multiple planned electrode sections 52 are composed of multiple wires or the like printed on surface 21 of circuit board 2. Planned mounting sections 51 are target locations where mounting of electronic components 4 are to be mounted on surface 21 of circuit board 2. Planned electrode sections 52 are target locations where electrodes 41 of electronic components 4 are to be disposed on surface 21 of circuit board 2. Multiple planned electrode sections 52 are formed within planned mounting sections 51. When each of planned mounting sections 51 of surface 21 of circuit board 2 is at predetermined position, component mounting device 10 mounts electronic component 4 on each planned mounting section 51.

Control device 30 of mounting system 1 shown in FIG. 2 includes a computer having a CPU, ROM, and RAM. Although not shown, component feeder 12, mounting head 16, moving mechanism 18, and operation panel 28 are communicably connected to control device 30. Control device 30 controls mounting of electronic components 4 on circuit board 2 by controlling these devices (12, 16, 18, 28, 32, etc). The control process by control device 30 will be described later.

Control device 30 includes memory section 31. Memory section 31 stores CAD data (an example of drawing information). The CAD data is drawing information in which surface 21 of circuit board 2 are drawn. The CAD data includes position information indicating the positions of multiple planned mounting sections 51 on surface 21 of circuit board 2. The CAD data includes position information indicating the positions of multiple planned electrode sections 52 on surface 21 of circuit board 2. In addition, control device 30 can generate a job file (an example of component mounting information) based on the CAD data. The job file is information used for mounting multiple electronic components 4 on surface 21 of circuit board 2.

Next, the operation of mounting system 1 will be described. In mounting system 1, first, moving mechanism 18 moves imaging unit 20 above circuit board 2 by moving imaging unit 20 in the X-direction and the Y-direction. As a result, camera 24 of imaging unit 20 is positioned above circuit board 2. Subsequently, camera 24 of imaging unit 20 images surface 21 of circuit board 2 in a state in which entire surface 21 of circuit board 2 falls within the imaging range. Image data of an image captured by camera 24 is transmitted to control device 30.

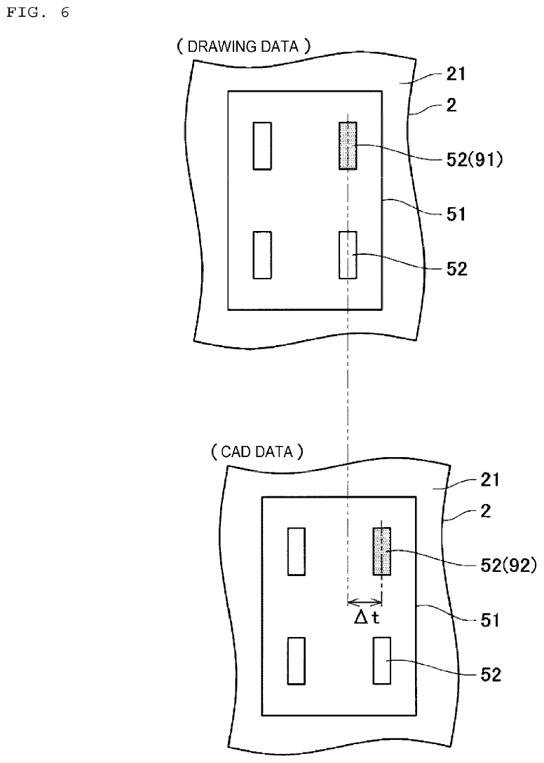

In mounting system 1, as shown in FIG. 5, a position comparison process is executed. In step S11 of the position comparison process, control device 30 receives the image data of surface 21 of circuit board 2 transmitted from camera 24. The image data includes an image of multiple planned mounting sections 51 and multiple planned electrode sections 52 on surface 21 of circuit board 2.

Next, in step S12, control device 30 compares specific position 91 in the received image data with specific position 92 in the CAD data stored in memory section 31. Specific position 91, 92 is, for example, the position of specific planned electrode section 52 among the multiple planned electrode sections 52 on surface 21 of circuit board 2. In the present embodiment, as shown in FIG. 6, the position of planned electrode section 52 shown colored in is defined as specific position 91, 92. Control device 30 compares the position information of specific position 91 in the image data (the upper side of the drawing) with the position information of specific position 92 in the CAD data (the lower side of the drawing).

Next, in step S13, control device 30 determines whether specific position 91 in the image data matches with specific position 92 in the CAD data. When the position information of specific position 91 and specific position 92 match with each other, control device 30 makes a YES determination in step S13 and the process proceeds to step S14. On the other hand, when the position information of specific position 91 and specific position 92 do not match with each other, control device 30 makes a NO determination and the process proceeds to step S21. In the example shown in FIG. 6, a positional deviation of Δt occurs on circuit board 2 between specific position 91 and specific position 92.

Next, in step S14, control device 30 recognizes that specific position 91 on circuit board 2 imaged by camera 24 matches with specific position 92 in the CAD data. As a result, control device 30 recognizes that multiple planned electrode sections 52 on surface 21 of circuit board 2 imaged by camera 24 are at the original predetermined positions. Further, control device 30 recognizes that multiple planned mounting sections 51 are at the original predetermined positions. That is, control device 30 recognizes that the actual positions of multiple planned mounting sections 51 and multiple planned electrode sections 52 on circuit board 2 match with the positions of multiple planned mounting sections 51 and multiple planned electrode sections 52 in the CAD data. Next, in step S15, control device 30 displays match information on operation panel 28. The match information is information indicating that there is no positional deviation between actual circuit board 2 and the CAD data.

Next, in step S16, control device 30 generates a job file. The job file includes, for example, information on mounting positions and mounting order of multiple electronic components 4. Control device 30 generates the job file based on the CAD data stored in memory section 31. Control device 30 acquires various pieces of position information from the CAD data and generates the job file.

On the other hand, in step S21 after the NO determination in step S13, control device 30 recognizes that specific position 91 on circuit board 2 imaged by camera 24 is different from specific position 92 in the CAD data. Thus, control device 30 recognizes that multiple planned electrode sections 52 on surface 21 of circuit board 2 imaged by camera 24 are not at the original predetermined positions. Further, control device 30 recognizes that multiple planned mounting sections 51 are not at the original predetermined positions. That is, control device 30 recognizes that the positions of multiple planned mounting sections 51 and multiple planned electrode sections 52 in actual circuit board 2 do not match with the positions of multiple planned mounting sections 51 and multiple planned electrode sections 52 in the CAD data. Next, in step S22, the control device 30 displays discrepancy information on operation panel 28. The discrepancy information is information indicating that a positional deviation has occurred between actual circuit board 2 and the CAD data. Control device 30 displays, for example, a warning on operation panel 28.

Next, in step S23, control device 30 generates a job file (an example of component mounting information). The job file is information used for mounting multiple electronic components 4 on surface 21 of circuit board 2. The job file includes, for example, information on mounting positions and mounting order of multiple electronic components 4. Control device 30 generates the job file based on the CAD data stored in memory section 31. Control device 30 acquires various pieces of position information from the CAD data and generates the job file. When generating the job file based on the CAD data, control device 30 generates the job file by correcting the position information indicating the positions of multiple planned mounting sections 51 and multiple planned electrode sections 52. Since a positional deviation occurs between actual circuit board 2 and the CAD data, control device 30 corrects the position information so as to compensate for the positional deviation.

In step S17 after steps S16 and S23, control device 30 transmits a mounting instruction to component mounting device 10 to mount multiple electronic components 4 on circuit board 2. Control device 30 transmits the mounting instruction based on the generated job file. Upon receiving the mounting instruction, component mounting device 10 mounts multiple electronic components 4 on circuit board 2. Component mounting device 10 mounts multiple electronic components 4 on circuit board 2 based on the job file.

Control device 30 executes each of the above-described processes for all of multiple component mounting devices 10. Each process executed by control device 30 is the same as each process described above, and therefore description thereof is omitted.

Mounting system 1 of the embodiment has been described above. As is apparent from the above description, mounting system 1 includes component mounting device 10, for mounting electronic component 4 on surface 21 of circuit board 2, and control device 30. Surface 21 of circuit board 2 is provided with planned mounting sections 51 on which mounting of electronic components 4 by component mounting device 10 is planned. Component mounting device 10 includes camera 24 for imaging surface 21 of circuit board 2. In addition, component mounting device 10 is configured to mount electronic components 4 on planned mounting sections 51 when planned mounting sections 51 of surface 21 of circuit board 2 are at predetermined positions. Control device 30 stores the CAD data in memory section 31, the CAD data depicting surface 21 of circuit board 2, on which electronic components 4 are mounted by component mounting device 10. Control device 30 compares specific position 92 in the CAD data stored in memory section 31 with specific position 91 in the image data of surface 21 of circuit board 2 imaged by camera 24 and recognizes that planned mounting section 51 of surface 21 of circuit board 2 is not at the predetermined position (see steps S12, S13, S21) if specific position 92 and specific position 91 do not match with each other.

Comparing the CAD data and the image data, the positions of planned mounting sections 51 in the CAD data and the positions of planned mounting sections 51 in the image data are supposed to be the same. However, due to some cause, the positions of planned mounting sections 51 in the CAD data and the positions of planned mounting sections 51 in the image data may deviate from each other. For example, before the step of mounting electronic components 4 on circuit board 2, a printing deviation may occur when wires are formed on surface 21 of circuit board 2 by printing, and thus planned mounting sections 51 may not be formed at the planned positions. In such a case, the positions of planned mounting sections 51 in the CAD data and the positions of planned mounting sections 51 in the image data are different from each other.

With the above configuration, by corn paring specific position 92 in the CAD data with specific position 91 in the image data, it is possible to recognize whether a positional deviation has occurred between specific position 92 and specific position 91. When specific position 92 in the CAD data and specific position 91 in the image data are different from each other, control device 30 recognizes that planned mounting sections 51 on surface 21 of circuit board 2 are not at predetermined positions. As a result, it is possible to determine whether planned mounting sections 51 are at the original intended positions for mounting electronic components 4. That is, by comparing specific position 92 and specific position 91, it is possible to determine whether a positional deviation of planned mounting sections 51 has occurred. As a result, even if the operator using component mounting device 10 does not visually check actual circuit board 2, it is possible to determine whether planned mounting sections 51 are at the original intended positions. If planned mounting sections 51 are not at the original intended positions, electronic components 4 cannot be mounted at the correct positions. Otherwise, electronic components 4 can be mounted at the correct positions. As described above, it is possible to easily determine whether electronic components 4 can be mounted at the correct positions.

Although one embodiment has been described above, specific embodiments are not limited to the embodiment described above. In the following description, the same components as those in the above description are denoted by the same reference numerals, and description thereof is omitted.

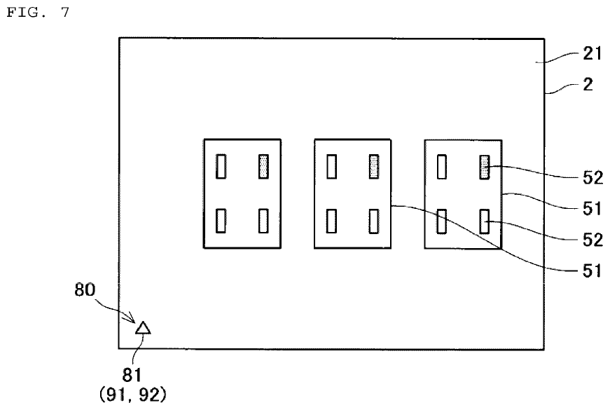

In the above-described embodiment, the position of specific planned electrode section 52 among multiple planned electrode sections 52 is defined as specific position 91, 92, but the present invention is not limited to this configuration. Specific position 91, 92 can be changed as appropriate. For example, the position of the edge of planned mounting section 51 of surface 21 of circuit board 2 may be defined as specific position 91, 92. Alternatively, as shown in FIG. 7, the position of mark 81 of a polygon (e.g., a triangle) displayed at corner 80 of surface 21 of circuit board 2 may be defined as specific position 91, 92. Mark 81 is printed on surface 21 of circuit board 2. Corner 80 is a part that is surrounded by two edges of circuit board 2.

While specific examples of the present invention have been described in detail above, these are illustrative only and are not intended to limit the scope of the claims. The techniques described in the claims include various modifications and variations of the specific examples illustrated above. The technical elements described in this specification or the drawings exhibit technical usefulness alone or in various combinations, and are not limited to the combinations described in the claims at the time of filing. In addition, the techniques illustrated in this specification or the drawings can simultaneously achieve multiple objectives, and the achievement of one of the objectives by itself has technical usefulness.

### REFERENCE SIGNS LIST

1: Mounting system
2: Circuit board
4: Electronic component
6: Suction nozzle
10: Component mounting device
12: Component feeder
14: Feeder holding section
16: Mounting head
18: Moving mechanism
18a: Movement base
20: Imaging unit
21: Surface
22: Camera support
24: Camera
26: Conveyance device
28: Operation panel
30: Control device
31: Memory section
32: Supporting device
34: Support pin
38: Support table
41: Electrode
51: Planned mounting section
52: Planned electrode section
80: Corner
81: Mark
91: Specific position
92: Specific position

1. A mounting system comprising a component mounting device configured to mount a component on a surface of a board, and a control device,
wherein a planned mounting section, at which mounting of a component by the component mounting device is planned, is provided on the surface of the board;
wherein the component mounting device comprises an imaging device, being configured to image the surface of the board, and mounts the component on the planned mounting section when the planned mounting section of the board surface is at a predetermined position, and
wherein the control device stores drawing information depicting the board surface on which the component is to be mounted by the component mounting device, compares a specific position in the stored drawing information with a specific position in image information of the board surface imaged by the imaging device, and recognizes that the planned mounting section of the board surface is not at the predetermined position when the specific position in the drawing information and the specific position in the image information are different.

2. The mounting system of claim 1,
wherein multiple component mounting devices are provided; and
wherein the control device stores, for each of the multiple component mounting devices, drawing information depicting the corresponding board surface at which a component is mounted by the component mounting device; and
compares a stored specific position in the drawing information with a specific position in the image information of the corresponding board surface imaged by the imaging device, and recognizes that the planned mounting section of the corresponding board surface is not at the predetermined position when the specific position in the drawing information and the specific position in the image information are different.

3. The mounting system of claim 1, wherein the control device is capable of generating component mounting information to be used for mounting a component on the board surface based on the stored drawing information, and when the planned mounting section of the board surface is not present at the predetermined position, corrects the position information indicating the position of the planned mounting section to generate the component mounting information.

4. The mounting system of claim 1, wherein the specific position in the drawing information and the specific position in the image information are positions where electrodes of a component to be mounted on the board surface are arranged.

5. The mounting system of claim 1, wherein the specific position in the drawing information and the specific position in the image information are a position of a polygonal mark displayed on a corner of the board surface.
